(19) United States
(12) Patent Application Publication
(10) Pub. No.: US 2026/0090155 A1
(43) Pub. Date: Mar. 26, 2026

(54) CHIP PACKAGE

(71) Applicant: GUANGZHOU LUXVISIONS INNOVATION TECHNOLOGY LIMITED, Guangzhou City (CN)

(72) Inventors: Pyng Yu, Guangzhou City (CN); Wei-Han Wu, Guangzhou City (CN)

(73) Assignee: GUANGZHOU LUXVISIONS INNOVATION TECHNOLOGY LIMITED, Guangzhou City (CN)

(21) Appl. No.: 19/291,619

(22) Filed: Aug. 6, 2025

Related U.S. Application Data
(60) Provisional application No. 63/699,765, filed on Sep. 26, 2024.

(30) Foreign Application Priority Data
Jan. 15, 2025 (CN) 202510063990.1

(51) Int. Cl. H10H 20/855; H10H 20/80; H10H 20/856

(52) U.S. Cl. CPC H10H 20/855; H10H 20/856; H10H 20/882

(57) ABSTRACT

A chip package includes a substrate, a light-emitting diode chip, and an optical layer. The light-emitting diode chip is disposed on the substrate along a stacking direction. The optical layer is disposed on the light-emitting diode chip along the stacking direction. A refractive index of the optical layer gradually decreases along the stacking direction.

### CROSS-REFERENCE TO RELATED APPLICATION

This application claims the priority benefit of U.S. provisional application Ser. No. 63/699,765, filed on Sep. 26, 2024 and China application serial no. 202510063990.1, filed on Jan. 15, 2025. The entirety of each of the above-mentioned patent applications is hereby incorporated by reference herein and made a part of this specification.

### BACKGROUND

### Technical Field

The disclosure relates to an optical device, and particularly relates to a chip package.

### Description of Related Art

Existing light-emitting diode chips are prone to total reflection at the light-emitting surface of the chip, resulting in low light extraction efficiency.

### SUMMARY

The disclosure provides a chip package, having good light extraction efficiency.

According to an embodiment of the disclosure, a chip package is provided, including a substrate, a light-emitting diode chip, and an optical layer. The light-emitting diode chip is disposed on the substrate along a stacking direction. The optical layer is disposed on the light-emitting diode chip along the stacking direction. A refractive index of the optical layer gradually decreases along the stacking direction.

According to an embodiment of the disclosure, the optical layer includes a first surface distant from the light-emitting diode chip and a second surface close to the light-emitting diode chip, and a refractive index of the optical layer at the first surface is greater than 1.0 and less than or equal to 1.2.

According to an embodiment of the disclosure, a refractive index of the optical layer at the second surface is less than or equal to 2.5.

According to an embodiment of the disclosure, the optical layer includes a plurality of optical sub-layers sequentially stacked along the stacking direction.

According to an embodiment of the disclosure, the chip package further includes fluorescence powder, disposed in the optical layer.

According to an embodiment of the disclosure, a particle size of the fluorescence powder gradually decreases along the stacking direction.

According to an embodiment of the disclosure, the chip package further includes a plurality of scattering particles, disposed in the optical layer.

According to an embodiment of the disclosure, the fluorescence powder and the plurality of scattering particles are disposed in different ones of the plurality of optical sub-layers, the fluorescence powder is disposed in at least one of the optical sub-layers close to the light-emitting diode chip, and the scattering particles are disposed in at least one of the optical sub-layers distant from the light-emitting diode chip.

According to an embodiment of the disclosure, the chip package further includes an insulation structure, disposed on the substrate and surrounding the light-emitting diode chip and the optical layer.

According to an embodiment of the disclosure, the optical layer includes a first surface distant from the light-emitting diode chip, the insulation structure includes a top surface distant from the substrate, and a distance between the top surface of the insulation structure and the substrate is greater than or equal to a distance between the first surface and the substrate.

According to an embodiment of the disclosure, the chip package further includes a metal reflection layer, disposed on a surface of the insulation structure facing the light-emitting diode chip and the optical layer.

According to an embodiment of the disclosure, the metal reflection layer includes a concave surface facing the light-emitting diode chip and the optical layer.

Based on the above, the chip package provided by an embodiment of the disclosure utilizes the optical layer with a graded refractive index to enhance the light extraction efficiency of the light-emitting diode chip, and also disposes fluorescence powder with color conversion function and scattering particles with light homogenization function in the optical layer. The chip package also conducts light concentration by using a metal reflection cup surrounding the light-emitting diode chip and the optical layer.

In order to make the above-mentioned features and advantages of the disclosure clearer and easier to understand, the following embodiments are given and described in details with the accompanying drawings as follows.

### BRIEF DESCRIPTION OF THE DRAWINGS

FIG. 1 is a schematic diagram of a chip package according to some embodiments of the disclosure.

FIG. 2 is a schematic diagram of an optical layer according to an embodiment of the disclosure.

FIG. 3 is a schematic diagram of an optical layer according to an embodiment of the disclosure.

FIG. 4 is a schematic diagram of a chip package according to an embodiment of the disclosure.

### DESCRIPTION OF THE EMBODIMENTS

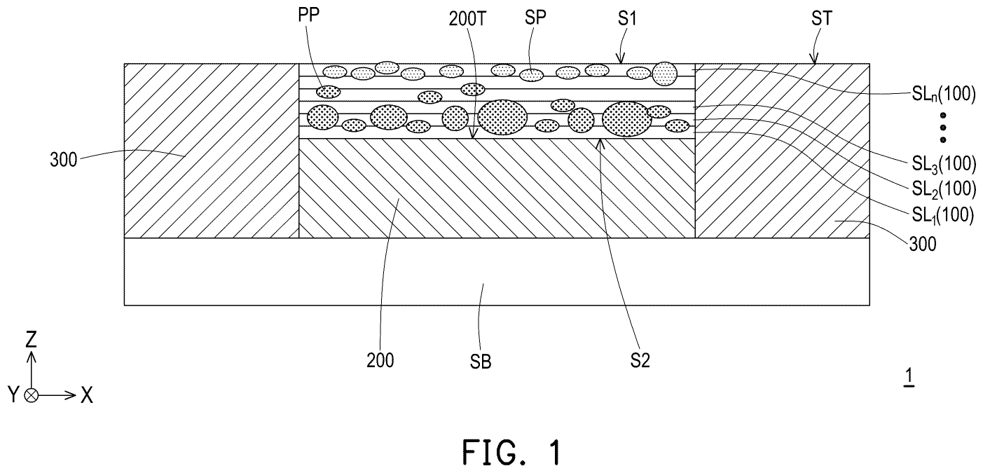

Referring to FIG. 1, FIG. 1 is a schematic diagram of a chip package according to some embodiments of the disclosure.

In a first embodiment of the disclosure, a chip package 1 includes a substrate SB, a light-emitting diode chip 200, an optical layer 100, and an insulation structure 300. The substrate SB is a circuit board. The light-emitting diode chip 200 is disposed on the substrate SB along a Z direction (stacking direction). The optical layer 100 includes a first surface S1 and a second surface S2, and is disposed on a light-emitting surface 200T of the light-emitting diode chip 200 along the Z direction. The second surface S2 directly contacts the light-emitting surface 200T. A refractive index of the optical layer 100 gradually decreases along the Z direction. Compared with a comparative example where no optical layer 100 is disposed on the light-emitting surface 200T of the light-emitting diode chip 200, the first embodiment, through configuring the optical layer 100 with a graded refractive index on the light-emitting diode chip 200, may avoid total reflection at the light-emitting surface 200T of the light-emitting diode chip 200, thereby enhancing the light extraction efficiency of the light-emitting diode chip 200. In some embodiments, the refractive index of the optical layer 100 may be continuously graded.

In some embodiments, a refractive index of the optical layer 100 at the second surface S2 is less than or equal to 2.5 for avoiding total reflection at the interface between the light-emitting diode chip 200 and the optical layer 100. Furthermore, a refractive index of the optical layer 100 at the first surface S1 is greater than 1.0 and less than or equal to 1.2 for avoiding total reflection at the interface between the optical layer 100 and air.

In a second embodiment of the disclosure, as shown in FIG. 1, the optical layer 100 includes a plurality of optical sub-layers SL₁, SL₂, SL₃ . . . . SLₙ sequentially stacked along the Z direction, where n is any positive integer greater than 3. The second surface S2 of the optical layer 100 is on the optical sub-layer SL₁, and the first surface S1 of the optical layer 100 is on the optical sub-layer SLₙ. The refractive indices of the plurality of optical sub-layers SL₁, SL₂, SL₃ . . . . SLₙ gradually decrease. The refractive index of the optical sub-layer SL₁ is greater than the refractive index of the optical sub-layer SL₂, the refractive index of the optical sub-layer SL₂ is greater than the refractive index of the optical sub-layer SL₃, and so on. The refractive index of the optical sub-layer SL₁ may be less than or equal to 2.5 for avoiding total reflection at the interface between the light-emitting diode chip 200 and the optical layer 100. The refractive index of the optical sub-layer SLₙ may be greater than 1.0 and less than or equal to 1.2 for avoiding total reflection at the interface between the optical layer 100 and air.

The chip package 1 may also include fluorescence powder PP and a plurality of scattering particles SP disposed in the optical layer 100. The fluorescence powder PP is used to absorb light from the light-emitting diode chip 200 for conducting color conversion and emitting fluorescence, and the scattering particles SP are used to homogenize light from the light-emitting diode chip 200. As shown in FIG. 1, the fluorescence powder PP and the scattering particles SP may be disposed in different optical sub-layers. In some embodiments, the fluorescence powder PP may be disposed in some optical sub-layers close to the light-emitting diode chip 200, and the scattering particles SP may be disposed in some optical sub-layers distant from the light-emitting diode chip 200, but the disclosure is not limited thereto.

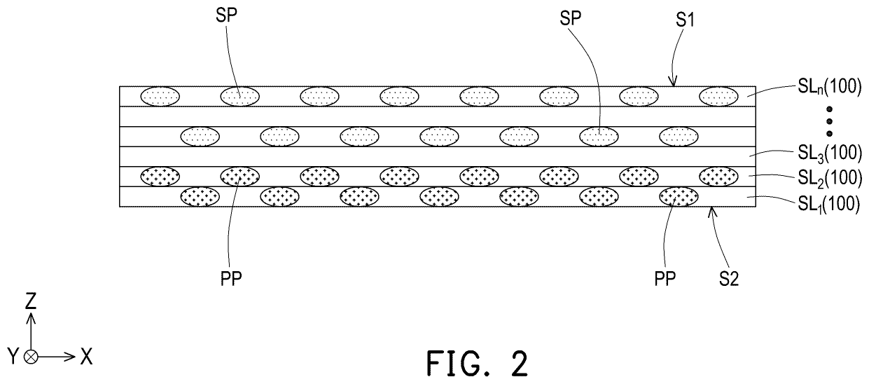

In a third embodiment of the disclosure, as shown in FIG. 2, the optical layer 100 includes the plurality of optical sub-layers SL₁, SL₂, SL₃ . . . . SLₙ sequentially stacked along the Z direction. The fluorescence powder PP and the plurality of scattering particles SP are uniformly distributed within the optical layer 100.

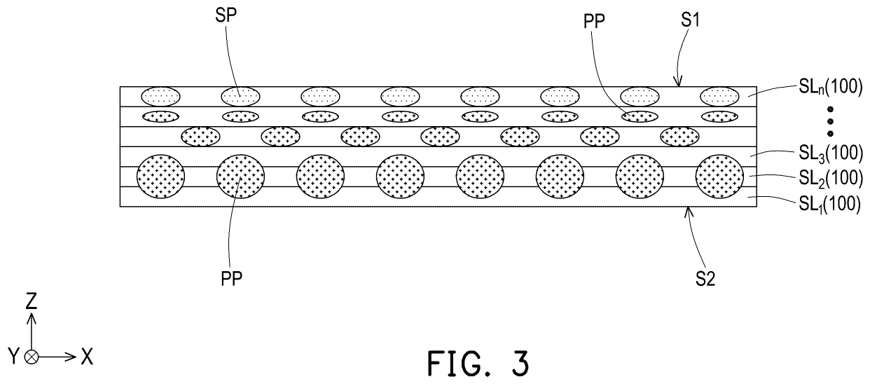

In a fourth embodiment of the disclosure, as shown in FIG. 3, the optical layer 100 includes the plurality of optical sub-layers SL₁, SL₂, SL₃ . . . . SLₙ sequentially stacked along the Z direction. The fluorescence powder PP is disposed in some optical sub-layers close to the second surface S2 (i.e., close to the light-emitting diode chip 200), and the scattering particles SP are disposed in some optical sub-layers close to the first surface S1 (i.e., distant from the light-emitting diode chip 200). The closer the fluorescence powder PP is to the second surface S2, the larger is its particle size; the further the fluorescence powder PP is from the second surface S2, the smaller is its particle size. Furthermore, the fluorescence powder PP with smaller particle size may be disposed corresponding to the gaps between the fluorescence powder PP with larger particle size for enhancing the color conversion efficiency.

In order to fully illustrate the various embodiments of the disclosure, other embodiments of the disclosure are described below. It should be mentioned here that, the following embodiments adopt the reference numerals of the embodiment above and a portion of the content thereof, wherein the same reference numerals are used to represent the same or similar devices and descriptions of the same technical content are omitted. The omitted portions are as described in the embodiment above and are not repeated in the embodiments below.

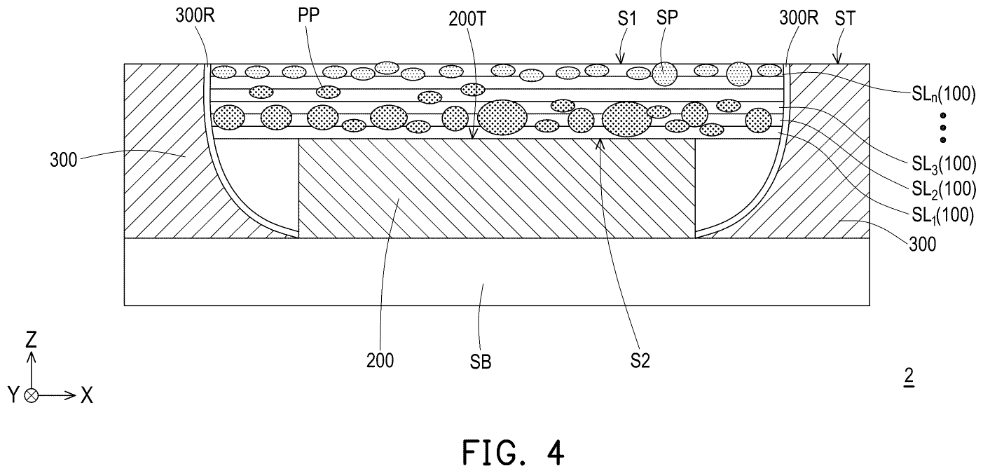

In a fifth embodiment of the disclosure, as shown in FIG. 4, a chip package 2 includes the substrate SB, the light-emitting diode chip 200, the optical layer 100, and the insulation structure 300. The insulation structure 300 is disposed on the substrate SB and surrounds the light-emitting diode chip 200 and the optical layer 100. The chip package 2 also includes a metal reflection layer 300R. The metal reflection layer 300R is disposed on a surface of the insulation structure facing the light-emitting diode chip 200 and the optical layer 100, and the metal reflection layer 300R includes a concave surface facing the light-emitting diode chip 200 and the optical layer 100. Accordingly, the metal reflection layer 300R constitutes a metal reflection cup, which may reflect light from the light-emitting diode chip 200 and the optical layer 100 for enhancing the forward light emission intensity of the chip package 2. In the chip package 2 shown in FIG. 4, the insulation structure 300 includes a top surface ST distant from the substrate SB, and a distance between the top surface ST and the substrate SB is equal to a distance between the first surface S1 and the substrate SB (as shown in FIG. 4, the top surface ST and the first surface S1 are coplanar), but the disclosure is not limited thereto. In some embodiments, the distance between the top surface ST and the substrate SB may be greater than the distance between the first surface S1 and the substrate SB for ensuring the light concentration function of the metal reflection cup.

Based on the above, the chip package provided by an embodiment of the disclosure utilizes the optical layer with a graded refractive index to enhance the light extraction efficiency of the light-emitting diode chip, and also disposes fluorescence powder with color conversion function and scattering particles with light homogenization function in the optical layer. The chip package also conducts light concentration by using a metal reflection cup surrounding the light-emitting diode chip and the optical layer.

What is claimed is:

1. A chip package, comprising:
a substrate;
a light-emitting diode chip, disposed on the substrate along a stacking direction; and
an optical layer, disposed on the light-emitting diode chip along the stacking direction,
wherein a refractive index of the optical layer gradually decreases along the stacking direction.

2. The chip package according to claim 1, wherein the optical layer comprises a first surface distant from the light-emitting diode chip and a second surface close to the light-emitting diode chip, and a refractive index of the optical layer at the first surface is greater than 1.0 and less than or equal to 1.2.

3. The chip package according to claim 2, wherein a refractive index of the optical layer at the second surface is less than or equal to 2.5.

4. The chip package according to claim 1, wherein the optical layer comprises a plurality of optical sub-layers sequentially stacked along the stacking direction.

5. The chip package according to claim 4, further comprising fluorescence powder, disposed in the optical layer.

6. The chip package according to claim 5, wherein a particle size of the fluorescence powder gradually decreases along the stacking direction.

7. The chip package according to claim 5, further comprising a plurality of scattering particles, disposed in the optical layer.

8. The chip package according to claim 7, wherein the fluorescence powder and the plurality of scattering particles are disposed in different ones of the plurality of optical sub-layers, the fluorescence powder is disposed in at least one of the optical sub-layers close to the light-emitting diode chip, and the scattering particles are disposed in at least one of the optical sub-layers distant from the light-emitting diode chip.

9. The chip package according to claim 1, further comprising an insulation structure, disposed on the substrate and surrounding the light-emitting diode chip and the optical layer.

10. The chip package according to claim 9, wherein the optical layer comprises a first surface distant from the light-emitting diode chip, the insulation structure comprises a top surface distant from the substrate, and a distance between the top surface and the substrate is greater than or equal to a distance between the first surface and the substrate.

11. The chip package according to claim 9, further comprising a metal reflection layer, disposed on a surface of the insulation structure facing the light-emitting diode chip and the optical layer.

12. The chip package according to claim 11, wherein the metal reflection layer comprises a concave surface facing the light-emitting diode chip and the optical layer.
